(19) United States
(12) Patent Application Publication
(10) Pub. No.: US 2026/0026320 A1
(43) Pub. Date: Jan. 22, 2026

(54) CLEAVING SYSTEMS AND METHODS FOR CLEAVING SEMICONDUCTOR STRUCTURES BY COMBINED THERMAL AND MECHANICAL STRESS INDUCTION

(71) Applicant: GlobalWafers Co., Ltd., Hsinchu (TW)

(72) Inventors: William L. Luter, St. Charles, MO (US); Peter D. Albrecht, O'Fallon, MO (US); Sumeet S. Bhagavat, St. Charles, MO (US)

(21) Appl. No.: 19/269,932

(22) Filed: Jul. 15, 2025

Related U.S. Application Data
(60) Provisional application No. 63/673,610, filed on Jul. 19, 2024.

(51) Int. Cl. H01L 21/762

(52) U.S. Cl. CPC H01L 21/76254

(57) ABSTRACT

Cleaving systems and methods for cleaving a semiconductor structure. The systems and methods may involve a combination of thermally and mechanically induced stress. The cleave system may include a vacuum chuck which deflects the semiconductor structure and a heater which heats the structure while the vacuum is applied. The combination of thermal and mechanical stress causes the structure to cleave along a cleave plane.

### CROSS-REFERENCE TO RELATED APPLICATIONS

This application claims the benefit of U.S. Provisional Patent Application No. 63/673,610, filed Jul. 19, 2024, which is incorporated herein by reference in its entirety.

### TECHNICAL FIELD

The field of the disclosure relates to cleaving apparatus for cleaving a semiconductor structure and to methods for cleaving semiconductor structures.

### BACKGROUND

Silicon on insulator materials (SOI) for semiconductor wafers are becoming increasingly important in many semiconductor devices. The production of such wafers by the layer transfer method involves the cleaving of a donor layer of silicon from one bonded wafer to another by cleaving separation.

Conventional methods for cleaving produce a top layer with poor thickness uniformity and are performed at relatively high temperatures which can damage the semiconductor wafer. Conventional methos also take a relatively long time to achieve the cleave. A need exists for new cleaving systems and cleaving methods which improve thickness uniformity, with reduced cleave temperatures and process time.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a method for cleaving a semiconductor structure having a top surface and a bottom surface generally parallel to the top surface. The bottom surface or top surface of the semiconductor structure is contacted with a vacuum chuck. There is a vacuum chamber formed between the vacuum chuck and the semiconductor structure. A vacuum is applied in the vacuum chamber to grasp the semiconductor structure and suspend the semiconductor structure in an inlet chamber. The vacuum is increased in the vacuum chamber to stress the semiconductor structure. The semiconductor structure is heated while applying the vacuum in the vacuum chamber to cleave the semiconductor structure along a cleave plane.

Another aspect of the present disclosure is directed to a method for preparing a silicon-on-insulator structure comprising a silicon top layer, a handle structure and dielectric layer disposed between the silicon top layer and handle structure. Ions are implanting into a donor structure to form a cleave plane in the donor structure. A handle structure is provided. A dielectric layer is formed on at least one of the donor structure and handle structure prior to bonding. The donor structure is bonded to the handle structure to form a bonded wafer structure comprising the donor structure, handle structure and a dielectric layer disposed between the handle structure and the donor structure. The bonded wafer structure is cleaved at the cleave plane such that a portion of the donor structure remains bonded to the handle structure as a silicon top layer. The cleave forms a silicon-on-insulator structure comprising the handle structure, silicon top layer and dielectric layer disposed between the handle structure and silicon top layer. The bonded wafer structure is cleaved by contacting a surface of the bonded wafer structure with a vacuum chuck. There is a vacuum chamber formed between the chuck and the bonded wafer structure. A vacuum is applied in the vacuum chamber to grasp the surface of the bonded wafer structure and suspend the bonded wafer structure in an inlet chamber. The vacuum in the vacuum chamber is increased to stress the bonded wafer structure. The bonded wafer structure is heated while applying the vacuum in the vacuum chamber to cleave the bonded wafer structure along the cleave plane.

A further aspect of the present disclosure is directed to a cleave system for cleaving a semiconductor structure. The cleave system includes a vacuum chuck for grasping and stressing the semiconductor structure. The vacuum chuck includes a chuck seal for forming a seal with a surface of the semiconductor structure, and includes a vacuum chamber, a chuck plate, and a channel. The vacuum chamber is radially inward of the chuck seal. The chuck plate forms an upper surface of the vacuum chamber for contacting the semiconductor structure while stressing the semiconductor structure. The channel extends through the chuck plate. The channel is in fluid communication with the vacuum chamber. The cleave system includes a heater disposed above and/or below the vacuum chuck for heating the semiconductor structure.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a perspective view of an embodiment of a cleave system for cleaving a semiconductor structure;

FIG. 2 is a cross-section view of the cleave system taken along line 2-2 in FIG. 1 with a semiconductor structure supported by the vacuum chuck;

FIG. 3 is another cross-section view of the cleave system taken along line 3-3 in FIG. 1;

FIG. 4 is another cross-section view of the cleave system taken along line 4-4 in FIG. 1;

FIG. 5 is a perspective view of a catch device of the cleave system;

FIG. 6 is a cross-section view of a donor structure having a donor wafer with a dielectric layer thereon;

FIG. 7 is cross-section view of the donor structure during ion implantation thereon;

FIG. 8 is a cross-section view of the donor structure bonded to a handle structure;

FIG. 9 is a cross-section view of a bonded wafer structure upon cleaving the donor structure at the cleave plane.

Corresponding reference characters indicate corresponding parts throughout the drawings.

### DETAILED DESCRIPTION

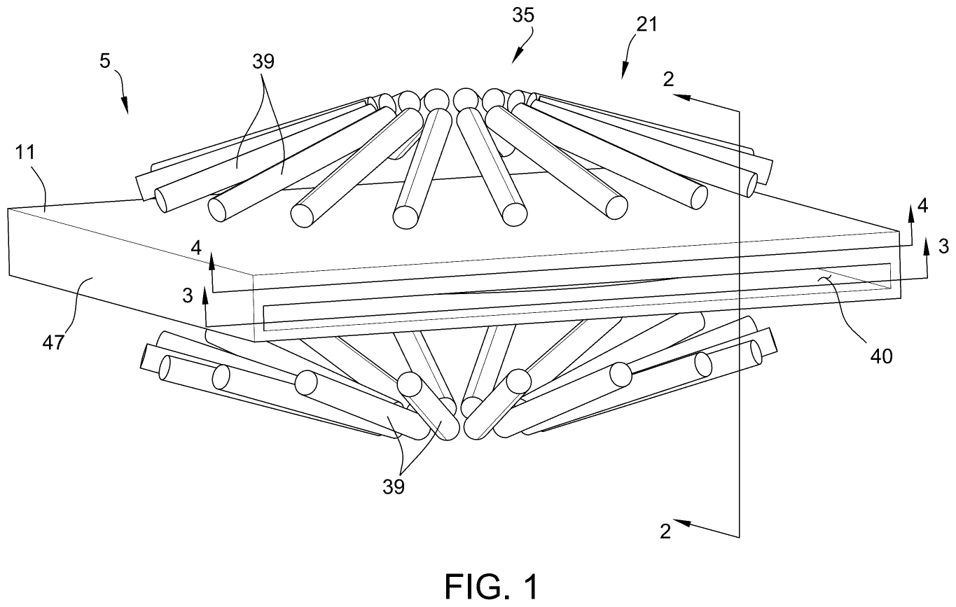

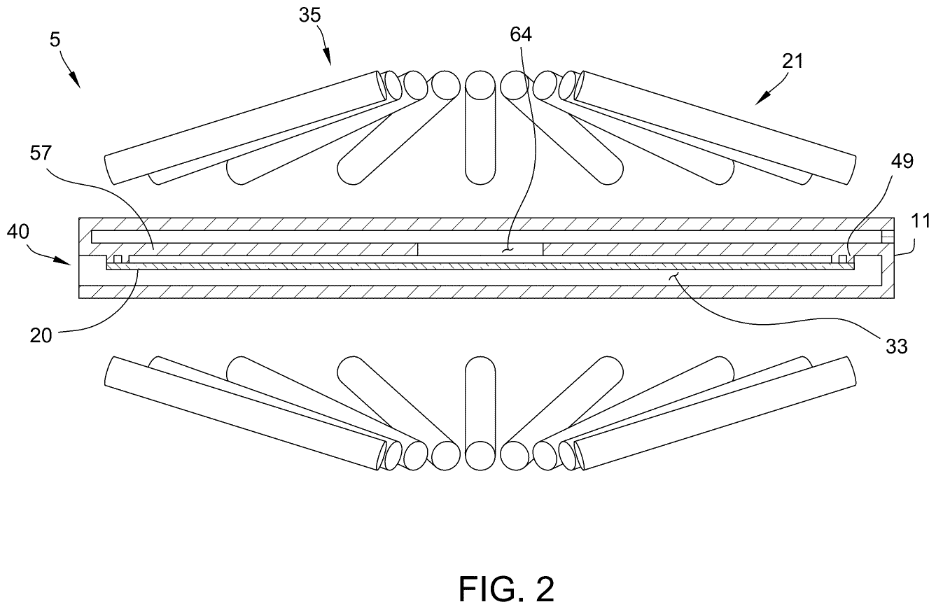

Referring now to FIG. 1, a cleave system 5 for cleaving a semiconductor structure 20 (FIG. 2) is shown. The semiconductor structure 20 which is cleaved in accordance with embodiments of the present disclosure may generally be any structure which cleaves upon application of stress to the semiconductor structure (e.g., deflection and/or thermal stress). Suitable structures may have a weakened zone formed within the structure such as a weakened zone formed by ion implantation. Some structures may include layered silicon-on-insulator structures (e.g., having a donor wafer disposed on a dielectric layer and handle wafer) which are cleaved to form the silicon-on-insulator structure (e.g., to form a silicon device layer on a dielectric layer disposed on a handle wafer by cleaving the donor wafer).

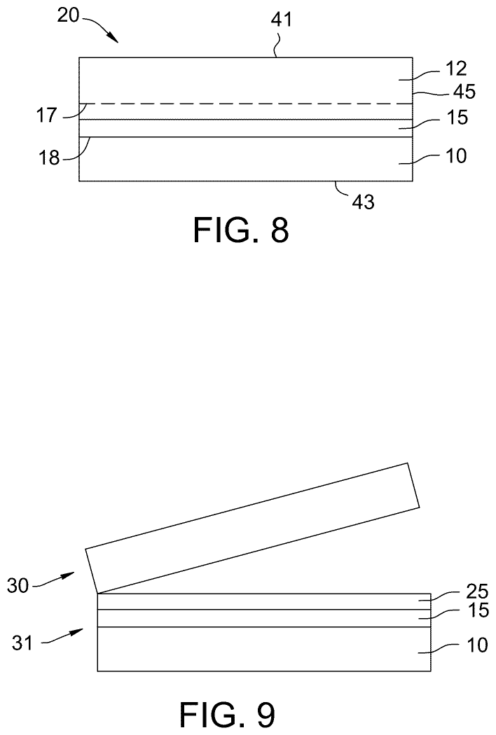

The semiconductor structure 20 includes a top surface 41 (FIG. 9) and a bottom surface 43 generally parallel to the top surface 41. The semiconductor structure 20 also includes outer circumference 45 that extends from the top surface 41 to the bottom surface 43. The structure 20 may generally have any suitable diameter (e.g., 200 mm, 300 mm or more).

The cleave system 5 includes a vacuum chuck 11 for grasping and stressing the semiconductor structure. A heater 21 is disposed above and below the vacuum chuck 11 for heating the semiconductor structure. While in the illustrated embodiment the heater 21 is disposed above and below the vacuum chuck 11, in other embodiments the heater 21 may be disposed only below or only above the vacuum chuck 11 (and in some embodiments the side opposite the heater may be actively cooled). The heater 21 may include a set of heating lamps 39 for heating the semiconductor structure. The vacuum chuck 11 may include a vacuum chuck outer housing 47 that is made of quartz to allow radiant heat to pass through the housing 47 to the semiconductor structure. In other embodiments, the heater may be a resistance heater. The vacuum chuck 11 and heater 35 may be disposed in a system housing (not shown).

The semiconductor structure 20 may be positioned in the cleave system 5 through an inlet 40. A robot may be used to position the semiconductor structure 20 in the vacuum chuck 11 and/or to remove the cleaved structure (i.e., lower structure that falls from the upper structure) and the remaining structure (i.e., upper structure). Once inserted through the inlet 40, the semiconductor structure 20 is disposed in an inlet chamber 33 (FIG. 2) until a vacuum is applied in the vacuum chuck 11. Depending on the structure 20 that is being cleaved and the position of the cleave plane, the semiconductor structure 20 may be positioned in the inlet chamber 33 such that its top or bottom surface is upward in the vacuum chuck 11.

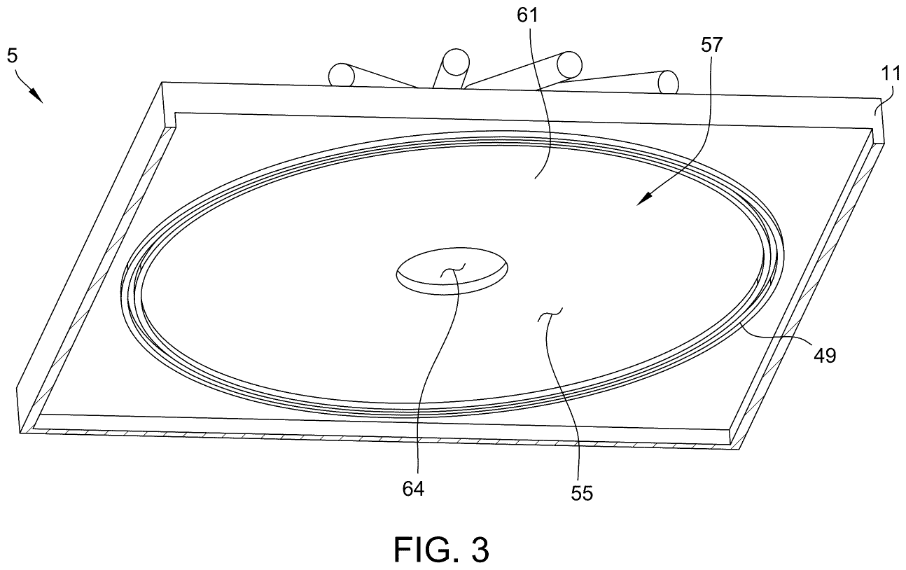

The cleave system 5 includes a chuck seal 49 (FIG. 3) that forms a seal with the surface of the semiconductor structure 20. The chuck seal 49 may be made of quartz or other ceramics or other materials coated with barrier materials such as silicon carbide, silicon nitride, or silicon. The chuck seal 49 may include two seal rings which provide redundancy (e.g., in the case of bypass of air when under vacuum) and increase the pressure drop across the seal 49. The chuck seal 49 may be inboard and a wafer notch.

A vacuum chamber 55 is disposed radially inward of the chuck seal 49. A vacuum within the vacuum chamber 55 causes the semiconductor structure to seal with the chuck seal 49. The inlet chamber 33 is disposed below the vacuum chamber 55.

The vacuum chuck 11 includes a chuck plate 57. The chuck plate 57 forms an upper surface 61 of the vacuum chamber 55 that contacts the semiconductor structure while stressing the semiconductor structure. The upper surface 61 may be dish-shaped or may be flat. The semiconductor structure is pressed (e.g., deflected) against the upper surface 61 while the vacuum is applied.

In some embodiments in which the upper surface 61 is dish-shaped, the shape of the dish may be adjusted so as to control the initiation of the cleave. For example, in embodiments in which the dish is spherical, the center of the sphere may be moved away from the center of the semiconductor structure so that the induced stress is not axis-symmetric along the centerline which increases the probability that the cleave will be initiated closer to the edge of the structure. This location can also be chosen by relationship to the earlier ion implant operation so that higher stress is concentrated at the point of high ion implant concentration.

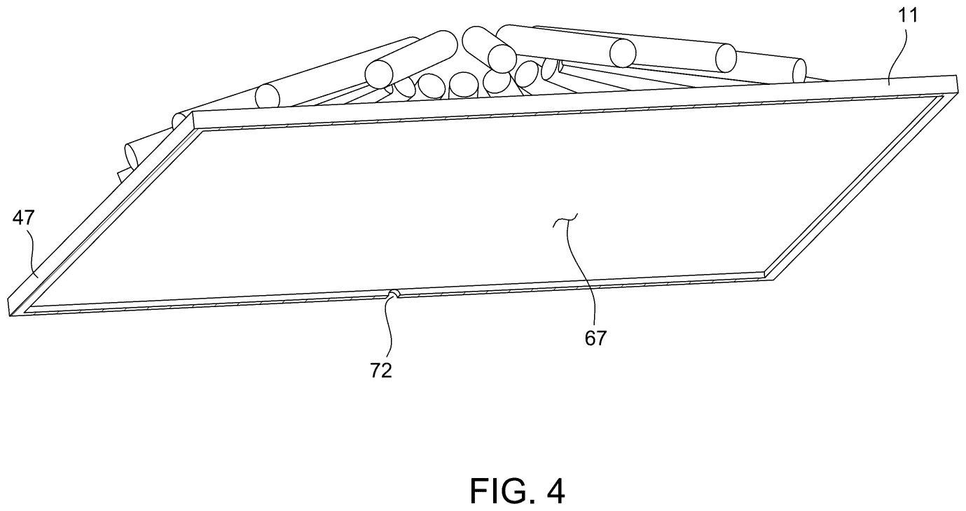

The vacuum is maintained in the vacuum chamber 55 through a channel 64 that extends through the chuck plate 57. The channel 64 is in fluid communication with the vacuum chamber 55 and a vacuum plenum 67 (FIG. 4) that is disposed above the chuck plate 57. The vacuum chuck outer housing 47 and the chuck plate 57 define the vacuum plenum 67. The vacuum plenum 67 is in fluid communication with a vacuum port 72 which is connected to a vacuum source (e.g., vacuum pump by vacuum conduits). The vacuum port 72 extends through the vacuum chuck outer housing 47.

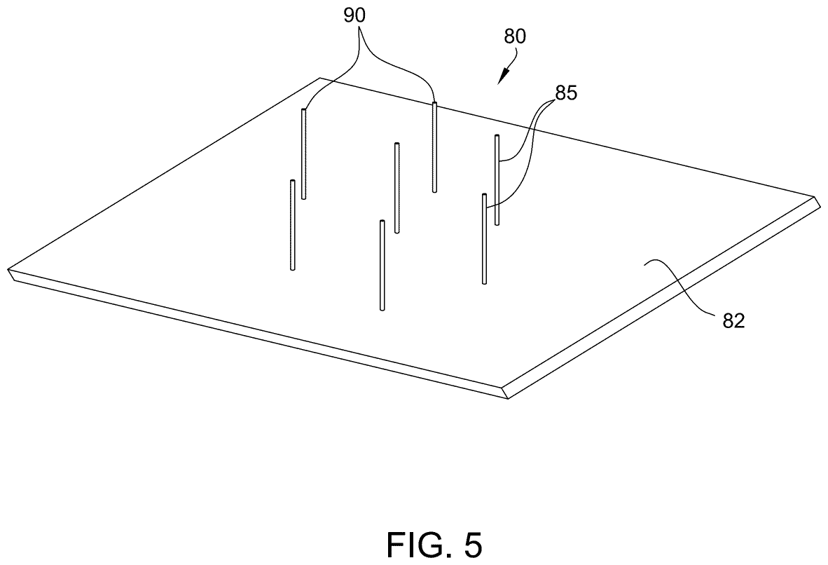

After cleaving, the lower piece of the semiconductor structure falls from the upper piece. A catch device 80 (FIG. 5) disposed below the lower piece may catch the lower piece as it falls. For example, the catch device 80 may include a pin plate 82 and a plurality of pins 85 that extend upward from the pin plate 82. The lower piece of the structure falls onto the upper surface 60 of each pin 85 upon cleaving.

To cleave the semiconductor structure 20, the semiconductor structure 20 is positioned in the inlet chamber 33 (FIG. 2) through the inlet 40. The surface (e.g., top or bottom surface depending on the structure and desired cleave) is contacted with the chuck seal 49 (e.g., by the robot or by lifting the catch device 80 to push the semiconductor structure 20 into proximity or contact with the vacuum chuck seal 49). The chuck seal 49 is generally coaxial with the semiconductor structure 20.

A vacuum is applied to the vacuum chamber 55 formed between the chuck seal 49, chuck plate 57, and the semiconductor structure 20. The vacuum in the vacuum chamber 55 causes the chuck seal 49 to grasp the semiconductor structure 20 and suspend the semiconductor structure 20 in the inlet chamber 33 (e.g., at 0.75 psi).

After the semiconductor structure 20 is suspended from the chuck seal 49, the vacuum in the vacuum chamber 4 is increased to stress the semiconductor structure 20. The semiconductor structure 20 deflects and contacts the upper surface 61 of the vacuum chamber 55. For example, the vacuum may be increased to at least 1 psi of vacuum, at least 2 psi of vacuum, at least 4 psi of vacuum, 1 to 10 psi of vacuum, or 1 to 7 psi of vacuum. In some embodiments, the pressure differential (atmosphere to vacuum) is pulsed (e.g., by a vibrating diaphragm) to induce a stress cycle in the semiconductor structure 20 to enhance the cleave. After the vacuum is increased, the vacuum chamber 4 may be held at the degree of vacuum until the semiconductor structure 20 cleaves.

While a vacuum is applied to the semiconductor structure 20, the semiconductor structure 20 is heated. For example, the semiconductor structure may be heated to a temperature of at least 300° C., at least 500° C., at least 750° C. or from 300° C. to 1000° C., or from 300° C. to 750° C. and held at such a temperature until the semiconductor structure 20 cleaves along the cleave plane (e.g., at least about 10 seconds, at least about 1 minute, at least about 15 minutes, at least about 1 hour at least about 3 hours or from 10 seconds 3 hours or 10 seconds to 1 minute). The atmosphere in the cleave system 5 may be inert (e.g., argon or nitrogen). The semiconductor structure is heated while vacuum is applied to further stress the semiconductor structure and cleave the semiconductor structure 20 along the cleave plane. The combination of pressure and heat causes the semiconductor structure 20 to cleave along the cleave plane. In some embodiments, heat (and optionally cooling) is cycled while vacuum is applied.

Generally, the cleave initiates centrally in the semiconductor structure, i.e., the cleave initiates radially inward from an outer circumference 45 of the semiconductor structure 20. The cleave then propagates toward the outer circumference 45.

The catch device 80 (FIG. 5) is raised below the semiconductor structure 20 before the semiconductor structure 20 is cleaved to catch the lower portion that separates from the structure. Once the cleave occurs, the lower portion may be removed through the inlet 40. The pressure in the vacuum chamber 55 is increased until the pressure reaches ambient pressure causing the remaining structure to be released from the chuck seal 49. The upper portion then falls on the catch device 80 to allow the upper portion to be removed through the inlet 40.

The methods of the present disclosure for cleaving may generally be used with any semiconductor structure in which it is desirable to cleave the structure into two parts. In some embodiments of the present disclosure, the cleave process of embodiments described above is incorporated into a method for preparing a silicon-on-insulator structure. Such structures may include a handle wafer, a silicon layer (sometimes referred to as a “silicon device layer” or “silicon top layer”) and a dielectric layer disposed between the handle wafer and silicon layer. The following is merely one example of methods and systems for preparing a silicon-on-insulator structure and other methods may be used unless stated otherwise.

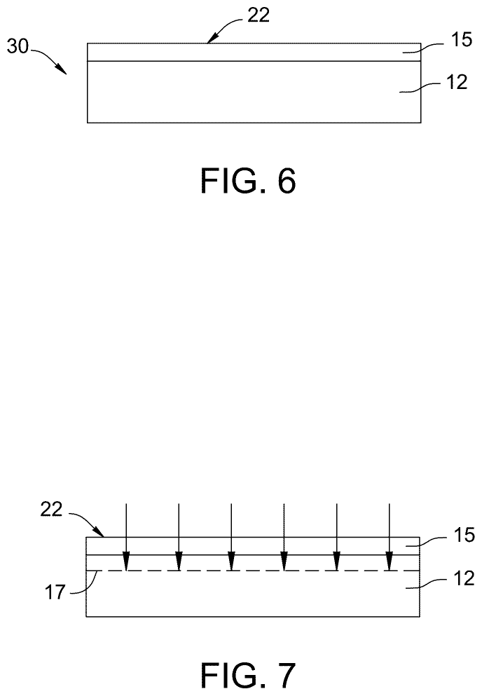

An example of a donor structure 30 that may be bonded to a handle structure to form a bonded wafer structure is shown in FIG. 6. The donor structure 30 may be formed with a dielectric layer 15 deposited on the front surface of a donor wafer 12. It should be understood that, alternatively, the dielectric layer 15 may be grown or deposited on the handle wafer or a dielectric layer may be grown on both the donor wafer and handle wafer and that these structures may be bonded in any of the various arrangements without limitation. Suitable donor wafers 12 may be composed of silicon, germanium, silicon germanium, gallium nitride, aluminum nitride, gallium arsenide, indium gallium arsenide and any combination thereof. In some embodiments, the donor wafer is composed of single crystal silicon.

The dielectric layer 15 may be any electrically insulating material suitable for use in a SOI structure, such as a material comprising SiO₂, Si₃N₄, aluminum oxide, or magnesium oxide. In some embodiments, the dielectric layer 15 is SiO₂ (i.e., the dielectric layer consists essentially of SiO₂). In embodiments in which the dielectric layer is silica (SiO₂), the dielectric layer is sometimes referred to as a “buried oxide” or “BOX” layer 15. The dielectric layer 15 may be applied according to any known technique in the art, such as thermal oxidation, wet oxidation, thermal nitridation or a combination of these techniques.

As shown for example in FIG. 7, ions (e.g., hydrogen atoms, helium atoms or a combination of hydrogen and helium atoms) may be implanted at a substantially uniform specified depth beneath the front surface 22 of the donor structure to define a cleave plane 17. It should be noted, that when helium and hydrogen ions are co-implanted into the structure to form the cleave plane 17, they may be implanted concurrently or sequentially. In some embodiments, ions are implanted prior to deposition of the dielectric layer 15. When implantation is performed prior to deposition of the dielectric layer 15, the subsequent growth or deposition of the dielectric layer on the donor wafer 12 is suitably performed at a temperature low enough to prevent premature separation or cleaving along plane 17 in the donor layer (i.e., prior to the wafer bonding process step).

The handle structure 10 (FIG. 8) may include a handle wafer obtained from any suitable material for preparing multi-layered structures, such as silicon, silicon carbide, sapphire, germanium, silicon germanium, gallium nitride, aluminum nitride, gallium arsenide, indium gallium arsenide, quartz and combinations thereof. The handle structure 10 may include a dielectric layer deposited on a handle wafer or, as in other embodiments, consists only of a handle wafer (i.e., does not include a dielectric layer). The handle wafer and donor wafer may be single crystal silicon wafers and may be single crystal silicon wafers which have been sliced from a single crystal ingot grown in accordance with conventional Czochralski crystal growing methods.

As shown in FIG. 8, the front surface of the dielectric layer 15 of the donor structure is suitably bonded to the front surface of the handle structure 10 to form a bonded wafer structure 20 through a bonding process. The dielectric layer 15 and handle structure 10 may be bonded together while performing a surface activation by exposing the surfaces of the structures to a plasma containing, for example, oxygen or nitrogen. The wafers are then pressed together and a bond at the bond interface 18 is formed there between. Generally speaking, wafer bonding may be achieved using essentially any technique known in the art, provided the energy employed to achieve formation of the bond interface is sufficient to ensure that the integrity of the bond interface is sustained during subsequent processing (i.e., layer transfer by separation along the cleave or separation plane 17 in the donor wafer).

Once prepared, the bonded wafer structure 20 is placed in the cleaving system 5 (FIGS. 1-5) to separate (i.e., cleave) a portion of the donor wafer along the cleave plane from the bonded structure to form the layered semiconductor structure (e.g., SOI structure). In this regard, the cleave results from mechanical and thermal stress applied to the bonded wafer structure and is not initiated from the circumference of the structure (such as a blade, knife or the like).

Referring to FIG. 9, upon separation, two structures 30, 31 are formed. Because the separation of the bonded wafer structure 20 occurs along the cleave plane 17 in the donor structure 12 (FIG. 7), a portion of the donor structure remains part of both structures (i.e., a portion of the donor wafer is transferred along with the dielectric layer 15). Structure 30 comprises a portion of the donor wafer. Structure 31 is the SOI structure and includes a handle structure 10, dielectric layer 15 and silicon top layer 25 (the portion of the donor wafer remaining after cleaving) disposed atop the dielectric layer 15. In embodiments in which the donor structure and handle structure both include a dielectric layer, the dielectric layers combine to form the dielectric layer 15 of the SOI structure.

The layers (handle structure 10, dielectric layer 15 and silicon top layer 25) of the SOI structure 31 may generally have any thickness that allows the layers to function as described herein. In some embodiments, the silicon top layer 25 is relatively thin (e.g., thickness of about 0.1 μm to about 0.3 μm) and the dielectric layer 15 is relatively thick (about 1.0 μm or more). In some embodiments, the SOI structure 31 is a fully-depleted SOI structure (FDSOI) with a silicon top layer 25 thickness of less than 130 nm and a box layer or less than 300 nm.

Compared to conventional cleaving methods, the methods of embodiments of the present disclosure have several advantages. Use of thermal and mechanical stress on the semiconductor structure allows for better thickness uniformity in the layer transfer. By coupling two stress sources, cleaving at lower temperatures may be possible, reducing wafer potential damage and reducing equipment complexity. Thermal cleaving (low surface roughness of the cleaved surface) may also be achieved at lower temperature. Advantages of mechanical cleaving (deterministic cleaving start, short process time) may be achieved while also producing good surface roughness. Cleave process time may be reduced compared to thermal cleaving processing, resulting in higher throughput.

In embodiments in which the center of a dish-shaped upper surface of the chuck is disposed away from the center of the semiconductor structure, the probability that the cleaving will be initiated closer to the edge is increased. This helps predict the cleave and improved the quality of the cleaved surface.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method for cleaving a semiconductor structure having a top surface and a bottom surface generally parallel to the top surface, the method comprising:
contacting the bottom surface or top surface of the semiconductor structure with a vacuum chuck, there being a vacuum chamber formed between the vacuum chuck and the semiconductor structure;
applying a vacuum in the vacuum chamber to grasp the semiconductor structure and suspend the semiconductor structure in an inlet chamber;
increasing the vacuum in the vacuum chamber to stress the semiconductor structure; and
heating the semiconductor structure while applying the vacuum in the vacuum chamber to cleave the semiconductor structure along a cleave plane.

2. The method as set forth in claim 1 wherein the cleave is initiated radially inward from an outer circumference of the semiconductor structure, the cleave propagating toward the outer circumference.

3. The method as set forth in claim 1 wherein the vacuum in the vacuum chamber is increased to at least 1 psi of vacuum.

4. The method as set forth in claim 1 further comprising raising a catch device before the semiconductor structure is cleaved along the cleave plane, wherein a lower piece of the cleaved semiconductor structure falls onto the catch device.

5. The method as set forth in claim 1 wherein the vacuum chuck comprises a chuck seal that forms a seal with the bottom or top surface, the vacuum chamber being radially inward of the chuck seal.

6. The method as set forth in claim 1 wherein the semiconductor structure is heated to a temperature of at least 300° C. while applying the vacuum in the vacuum chamber to cleave the semiconductor structure along the cleave plane.

7. The method as set forth in claim 1 wherein the vacuum chamber has an upper surface, the semiconductor structure contacting the upper surface while applying the vacuum in the vacuum chamber to stress the semiconductor structure, the upper surface being dish-shaped.

8. A method for preparing a silicon-on-insulator structure comprising a silicon top layer, a handle structure and dielectric layer disposed between the silicon top layer and handle structure, the method comprising:
implanting ions into a donor structure to form a cleave plane in the donor structure;
providing a handle structure;
forming a dielectric layer on at least one of the donor structure and handle structure prior to bonding;
bonding the donor structure to the handle structure to form a bonded wafer structure comprising the donor structure, handle structure and a dielectric layer disposed between the handle structure and the donor structure;
cleaving the bonded wafer structure at the cleave plane such that a portion of the donor structure remains bonded to the handle structure as a silicon top layer, the cleave forming a silicon-on-insulator structure comprising the handle structure, silicon top layer and dielectric layer disposed between the handle structure and silicon top layer, wherein the bonded wafer structure is cleaved by:
contacting a surface of the bonded wafer structure with a vacuum chuck, there being a vacuum chamber formed between the chuck and the bonded wafer structure;
applying a vacuum in the vacuum chamber to grasp the surface of the bonded wafer structure and suspend the bonded wafer structure in an inlet chamber;
increasing the vacuum in the vacuum chamber to stress the bonded wafer structure; and
heating the bonded wafer structure while applying the vacuum in the vacuum chamber to cleave the bonded wafer structure along the cleave plane.

9. The method as set forth in claim 8 wherein the cleave is initiated radially inward from an outer circumference of the bonded wafer structure, the cleave propagating toward the outer circumference.

10. The method as set forth in claim 8 wherein the vacuum in the vacuum chamber is increased to at least 2 psi of vacuum and wherein the bonded wafer structure is heated to a temperature of at least 300° C. while applying the vacuum in the vacuum chamber to cleave the bonded wafer structure along the cleave plane.

11. The method as set forth in claim 8 wherein the vacuum chuck comprises a chuck seal that forms a seal with the surface, the vacuum chamber being radially inward of the chuck seal.

12. The method as set forth in claim 8 wherein the vacuum chamber has an upper surface, the bonded wafer structure contacting the upper surface while applying the vacuum in the vacuum chamber to stress the bonded wafer structure, the upper surface being dish-shaped.

13. A cleave system for cleaving a semiconductor structure, the system comprising:
a vacuum chuck for grasping and stressing the semiconductor structure, the vacuum chuck comprising:
a chuck seal for forming a seal with a surface of the semiconductor structure;
a vacuum chamber radially inward of the chuck seal;
a chuck plate, the chuck plate forming an upper surface of the vacuum chamber for contacting the semiconductor structure while stressing the semiconductor structure;
a channel that extends through the chuck plate, the channel being in fluid communication with the vacuum chamber; and
a heater disposed above and/or below the vacuum chuck for heating the semiconductor structure.

14. The cleave system as set forth in claim 13 wherein the heater comprises a set of heating lamps.

15. The cleave system as set forth in claim 13 wherein the heater is disposed above and below the vacuum chuck.

16. The cleave system as set forth in claim 13 comprising a vacuum plenum disposed above the vacuum chuck.

17. The cleave system as set forth in claim 16 comprising a vacuum chuck outer housing, the vacuum chuck outer housing and chuck plate defining the vacuum plenum.

18. The cleave system as set forth in claim 13 comprising an inlet chamber for receiving the semiconductor structure, the inlet chamber being disposed below the vacuum chamber.

19. The cleave system as set forth in claim 13 comprising pins for catching a lower piece of the semiconductor structure upon cleaving.

20. The cleave system as set forth in claim 13 wherein the upper surface of the vacuum chamber is dish-shaped.
